(19) United States
(12) Patent Application Publication
(10) Pub. No.: US 2007/0087529 A1
(43) Pub. Date: Apr. 19, 2007

(54) Simulation method of wafer warpage

(75) Inventors: Won-Young Chung, Hwaseong-si (KR); Tai-Kyung Kim, Anyang-si (KR); Young-Kwan Park, Suwon-si (KR); Ui-Hui Kwon, Hwaseong-si (KR); Kyu-Baik Chang, Yongin-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/580,352

(22) Filed: Oct. 13, 2006

(30) Foreign Application Priority Data
Oct. 14, 2005 (KR) 10-2005-0097035

(51) Int. Cl. H01L 21/30; H01L 21/46

(52) U.S. Cl. 438/457

(57) ABSTRACT

Disclosed is a simulation method for determining wafer warpage. This method includes dividing layers and evaluating a composition ratio of materials composing the layers. The method mathematically transforms a semiconductor device, which is constructed as a complicated structure with various materials, into a simplified, mathematically equivalent stacked structure comprising a plurality of unit layer, and utilizes values of mechanical characteristics, which are obtained from the transformed layer structure, for estimating wafer warpage. As a result, it is possible to complete an operation of wafer warpage simulation using information about pattern density of the semiconductor device.

### CROSS-REFERENCE TO RELATED APPLICATIONS

This U.S. non-provisional patent application claims priority under 35 U.S.C. § 119 of Korean Patent Application 2005-97035 filed on Oct. 14, 2005, the entire contents of which are hereby incorporated by reference.

### BACKGROUND

The present invention is concerned with methods of simulating wafer warpage to estimate the degree of wafer twisting after completing semiconductor device manufacture.

A semiconductor device is typically comprised of plural pattern layers formed on a wafer. A particular desired semiconductor layout can be transferred onto the wafer to form a pattern layer, and various patterns can thus be formed on a wafer.

Material films used in fabricating the layers of a semiconductor device have inherent stresses. The stress of the film resulting from deposition and thermal processes commonly causes wafer warpage. Wafer warpage is usually more deepened after grinding the backside of wafer before the step of dividing the wafer into individual semiconductor chips.

Wafer warpage persists and causes processing defects even after completion of the steps of processing wafer backside grinding and chip division, and such defects affect uniformity and film deposition and patterning even during fabrication processing steps. Therefore, techniques are needed for preliminarily estimating and correcting such wafer warpage.

As a wafer typically includes multiple, complicated pattern layers, it is almost impossible to exactly evaluate the stress according to the structure of the pattern layers. Several ways have been proposed for estimating wafer warpage using simulation tools, e.g., finding an estimation value of chip or wafer-scaled warpage after calculating stress based on a sampling of wafer segments, or finding an estimated warpage value based on testing a multiplicity of stacked layers or unit films on a wafer.

These conventional techniques may be able to conduct wafer or chip-scaled warpage estimation in a simple pattern structure or in a stacked pattern structure with plural unit films. However, the first mentioned approach has a disadvantage of increasing errors in cases of material distribution heterogeneities in certain locations, while the second mentioned approach cannot be used to estimate warpage on a wafer where various materials are contained in a single layer.

These and other limitations of the prior art techniques in this field are overcome in whole or at least in part by the methods of this invention.

### SUMMARY OF THE INVENTION

The present invention is therefore generally directed to methods for simulating wafer warpage resulting from stress by various materials in the layers formed on a wafer.

The invention is also directed to methods for simulating wafer warpage in a multi-level pattern structure that includes a complicated pattern formed with various materials.

Further, the invention is also directed to methods for simulating and/or estimating chip-scaled warpage after a semiconductor chip division step, as well as for simulating and/or estimating wafer-scaled warpage both before and after grinding the back side of a wafer.

In order to achieve the desired objectives, the present invention provides methods for simulating wafer warpage. An illustrative invention embodiment includes the step of abstracting equivalent characteristic values of the several layers of a semiconductor device from composition ratios of materials comprising such layers. This method further comprises the steps of dividing layers of a semiconductor chip on a wafer, and calculating composition ratios of the materials forming each such layer. The layer used in such method may be a layer based on dividing the device along horizontal planes at which the materials discontinuously vary in composition, into pluralities of layers stacked vertically including the wafer. The composition ratios of the materials forming each such layer may be calculated from areal ratios designed in a semiconductor pattern layout. For example, areal occupation ratios may be used as the composition ratios of the materials in a layer when each layer is cut off along horizontal planes.

Equivalent characteristic values of the layers, which are transformed into mathematically equivalent unit film structures, are evaluated from the composition ratios and characteristic values of the materials forming the layers. The equivalent characteristic values represent characteristic values of the layers in the case of a wafer including stacked layers composed of unit films having the equivalent characteristic values. The equivalent characteristic values may be average values of characteristics based on the composition ratios of the materials forming the layer.

Simulation methods for wafer warpage estimation, and simulation tools for estimating characteristic values affecting wafer warpage and effects thereof based on characteristic values, are generally known. Based on such methods and tools, the present invention is able to estimate wafer warpage in application with a stacked structure of layers, which have equivalent characteristic values.

A further understanding of the nature and advantages of the present invention will be realized by reference to the remaining portions of this specification and the attached drawings.

### BRIEF DESCRIPTION OF THE DRAWINGS

The accompanying figures are included to provide a further understanding of the invention, and are incorporated in and constitute a part of this specification. The drawings illustrate exemplary embodiments of the invention and, together with the description, serve to explain principles of the present invention. In the figures:

FIG. 1 is a schematic cross-sectional view illustrating an example of a semiconductor device that can be used for describing the methods of this invention;

FIG. 2 is a schematic cross-sectional view illustrating a simplified multi-level stacked structure based on a mathematical structural transformation in accordance with the methods of this invention from the semiconductor device structure shown in FIG. 1;

FIG. 3 is a flow chart illustrating the steps in a method for simulating wafer warpage in accordance with an embodiment of the invention;

FIGS. 4 and 5 are schematic cross-sectional views illustrating an embodiment according to the invention; and

FIGS. 6 and 7 are graphs illustrating the results of carrying out a wafer warpage simulation according to an embodiment of the invention.

### DETAILED DESCRIPTION OF PREFERRED EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout the specification and in the drawings.

In the figures, it will be understood that the dimensions of certain layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, or one or more intervening layers may also be present. In addition, it will also be understood that when a layer is referred to as being ‘between’ two layers, it can be the only layer between the two layers, or one or more additional layers may also be present between the two layers.

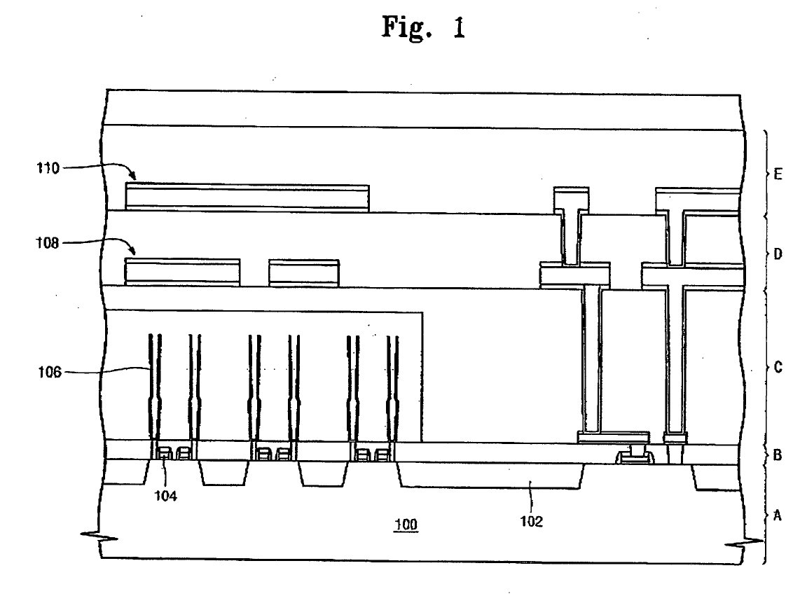

FIG. 1 is a schematic cross-sectional view illustrating an example of a semiconductor device, e.g., a DRAM, that can be used for describing the methods of this invention.

Referring to the DRAM semiconductor device illustrated in FIG. 1, field isolation films 102 are formed in a substrate 100 to define active regions. On the active regions are formed pluralities of pattern layers. The structure of the semiconductor device can be divided into plural levels comprising: a substrate layer A that includes the substrate 100 and the active regions; a gate layer B that includes gate patterns 104; a capacitor layer C that includes capacitors 106; first and second interconnection layers D and E respectively that include multi-level interconnections 108 and 110; and a passivation layer that is not labeled.

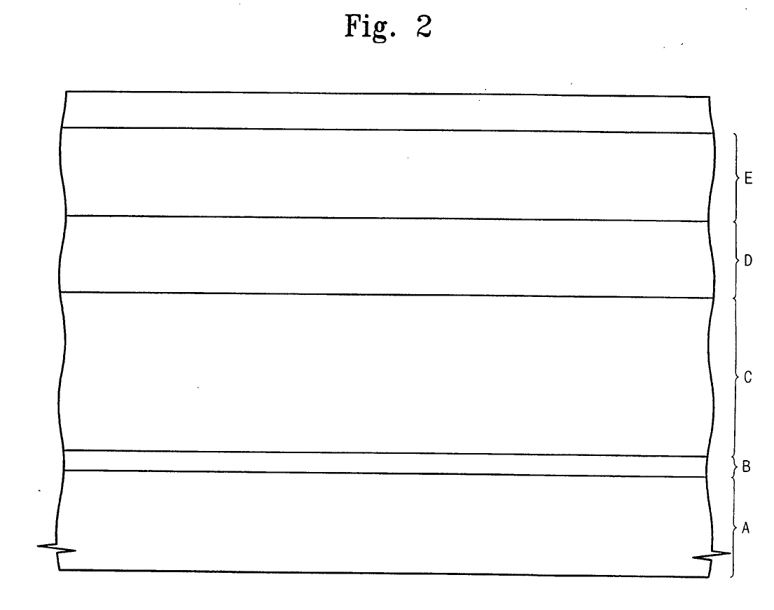

FIG. 2 is a schematic cross-sectional view illustrating a simplified multi-level stacked structure based on a mathematical structural transformation in accordance with the methods of this invention from the structure of the semiconductor device shown in FIG. 1.

Each layer of the semiconductor device shown in FIG. 1 is composed of plural patterns. The patterns constituting each layer are disposed with a predetermined pattern density in accordance with a pre-designed layout. The present invention in part comprises a step of mathematically transforming each layer of the complicated layer structure of FIG. 1 into a substantially equivalent layer comprising a single material film, e.g., modifying the complicated structure of FIG. 1 into a substantially equivalent multi-level stacked structure of unit layers as shown in FIG. 2, followed by a step of estimating wafer warpage based on the dimensions and material characteristics of the mathematically transformed structure.

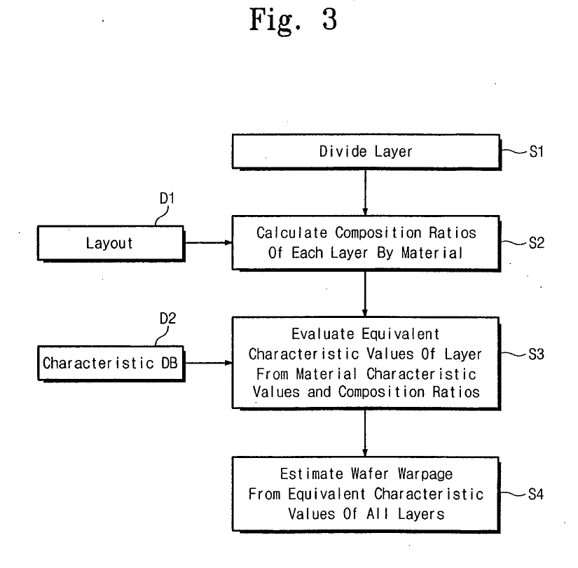

FIG. 3 is a flow chart illustrating the steps in a method for simulating wafer warpage in accordance with an embodiment of the invention.

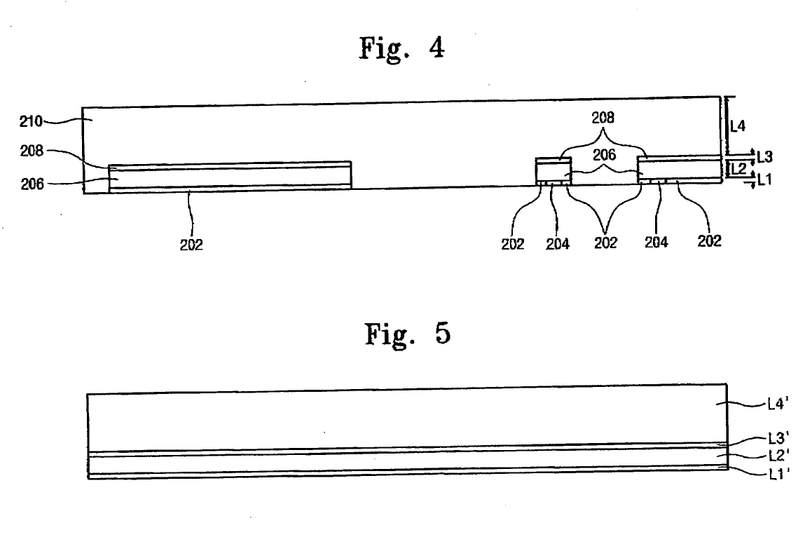

FIGS. 4 and 5 are schematic cross-sectional views illustrating an embodiment according to the invention. More particularly, FIG. 4 shows in isolation from the other layers a section of the second interconnection layer E of FIG. 1. FIG. 5 shows a transformed version of the second interconnection layer E, illustrating a transformed structure comprised of the substantially equivalent layer components with unit levels in accordance with an embodiment of the invention.

As illustrated in FIG. 4, the second interconnection layer E of FIG. 1 may, for example, be comprised of a barrier metal layer 202 and a partial via pattern 204, an interconnection metal layer 206, a capping layer 208, and an interlevel insulation film 210. The barrier metal layer 202, the via pattern 204, the interconnection metal layer 206, and the capping layer 208 may be arranged as shown in a complicated plane structure by the pre-designed layout. The methods of this invention, however, can mathematically simplify this complicated structure.

Referring to FIG. 3, the simulation method of this invention for estimating wafer warpage includes a first step of dividing the semiconductor device structure into the component multi-level layers (step S1), for example, macro layers A, B, C, D and E. The semiconductor device may be divided into pluralities of such macro layers, each comprised in turn of plural stacked layers. The various macros layers may thus be divided along virtual horizontal planes defined by locations at which materials discontinuously vary in composition. For instance, the second interconnection macro layer E can be differentiated into: (a) a first layer L1 composed of the barrier metal layers 202, the partial via patterns 204, and parts of the interlevel insulation film 210 between the barrier metal layers 202; (b) a second layer L2 composed of the interconnection metal layers 206 and parts of the interlevel insulation film 210 between the interconnection metal layers 206; (c) a third layer L3 composed of the capping layers 208 and parts of the interlevel insulation film 210 between the capping layers 208; and (d) a fourth layer L4 composed of a part of the interlevel insulation film 210 formed over the capping layers 208.

A thickness of each such layer L1, L2, L3 and L4 may be determined as an interval between the upper and lower virtual horizontal planes (at which materials discontinuously vary in composition) that define each such layer. This layer division step as aforementioned may be practically applied to the semiconductor substrate and to each of the macro pattern layers stacked on the semiconductor substrate, thereby enabling wafer warpage to be estimated in the manner described below.

After dividing the wafer into the plural stacked layers, as described above, the next step is to calculate composition ratios according to the materials in the layers (step S2 of FIG. 3). The composition ratios of materials forming the layers can be easily obtained from the pre-designed layout D1, input into the method as shown in FIG. 3. From the layout D1, one can obtain plane pattern structures of pattern layers and areal occupation ratios of the patterns. The steps S1 and S2 are thus carried out to obtain the necessary mathematical values, namely the thicknesses of the divided layers and the composition ratios of materials forming the layers, to carry out the mathematical transformation of the structure.

The next step (step S3) of the method is to evaluate mechanical characteristic values of the layers from the mechanical characteristic values and composition ratios of the materials that comprise the layers. This is done by cooperatively applying the mechanical characteristic values of the materials to the thickness and composition ratios obtained by the steps S1 and S2 above. In general, wafer warpage is caused by inherent stress of the materials and stress due to deposition and thermal treatment steps during the semiconductor fabrication process. Stress values of materials and characteristic values inducing stress have been identified and disclosed in the art. Thus, the mechanical characteristic values of the materials, which induce warpage of the wafer, may be obtained from an established database (DB) of the predetermined mechanical characteristics D2, input into the method as shown in FIG. 3. Relevant information from database (DB) is electronically or otherwise input to step S3 of the illustrated method to enable carrying out this step of evaluating equivalent characteristic values of the layers.

The stress of the materials is well known as being mathematically related to a degree of wafer warpage according to Stoney's formula as follows:

$${σ}_{f} = {E}_{s} \frac{{t}_{s}^{2}}{6 ( 1 - {v}_{s} ) {t}_{f}} ( {κ}_{e} - {κ}_{i} ) \qquad [ Formula 1 ]$$

In Formula 1, Eₛ represent Young's modulus, vₛ, is Poisson's ratio, tₛ is wafer thickness, t_{f} is film thickness, Kₑ is radius of curvature before deposition, and Kᵢ is radius of curvature after deposition.

In Stoney's formula (Formula 1 above), σ_{f}, Eₛ, and vₛ are well-known inherent values according to deposition and thermal treatment of a film. When layers of unit films are stacked in plurality on a wafer, Stoney's formula can be used effectively to estimate warpage of the wafer. But, when layers with complicated film structures are stacked in plurality on a wafer, Stoney's formula will not provide an accurate, reliable estimate of wafer warpage. However, the present invention provides methods for mathematically transforming the complicated layer structure of various material films (for example, a macro layer as illustrated in FIG. 4) into the equivalent layer structure comprised of unit films through the steps S1, S2 and S3. The mechanical characteristic value of the layer structure with unit films may be established as an average based on the composition ratio of the materials forming the layer. A further example of applying this method is shown in Table 1 below.

TABLE 1
Characteristic Values

| | | Young's | Poisson's |
|---|---|---|---|
| | Stress (MPa) | modulus (GPa) | ratio |
| Interlevel dielectric | −100 | 100 | 0.25 |
| (HDP layer) | | | |
| Interconnection | 300 | 50 | 0.3 |
| metal layer | | | |
| Barrier metal layer | 500 | 200 | 0.18 |
| Capping layer | −1000 | .00 | 0.2 |

Thus, when the second interconnection layer E uses materials suitable for the mechanical characteristics listed in Table 1, and the layer pattern has a layout where the areal occupation ratios of the interconnection metal layer 206 and the via pattern 204 are set at 60% and 2% respectively, the composition ratios of the layers are as summarized in Table 2 below.

When the interconnection metal layer 206 and the via pattern 204 are formed of the same metal and their areal occupation ratios are 60% and 20% in the layout, the capping layer 208 has the same areal occupation ratio as the interconnection layer 206 i.e., 60% of the layout, and the interlevel insulation film 210 between the interconnection metal layers 206 has 40% of the layout in areal occupation ratio. Also, an areal occupation ratio of the barrier metal layer 202 in the layout would be 58%, based on the percentages of the interconnection metal layer 206 and the via pattern 204.

TABLE 2
Composition Ratios

| | Interconnection | Interlevel | Barrier | Capping |
|---|---|---|---|---|
| | metal layer | insulation layer | metal layer | layer |
| 1'th layer | 2% | 40% | 58% | |
| 2'nd layer | 60% | 40% | 0% | |
| 3'rd layer | 0% | 40% | 0% | |
| 4'th layer | 0% | 100% | 0% | |

From the characteristic values of Table 1 and the composition ratios of Table 2, it is possible to obtain equivalent characteristic values of the mathematically modified layers based on unit films. One approach here is to use average values, to which the composition ratios of materials forming the layer are applied, which then can be evaluated by means of various ways of calculating average values. Alternatively, however, a technique of linear summation may be used to obtain the equivalent characteristic values of the first layer L1, as follows:
Stress (σ)=−100×0.4+300×0.2+500×0.58=256
Young's modulus=100×0.4+50×0.2+200×0.58=157
Poisson's ratio=0.25×0.4+0.3×0.2+0.18×0.58=0.21

Similar to the aforementioned procedure, the same mathematical operations can be applied for evaluating equivalent characteristic values of the second through fourth layers L2, L3 and L4. The equivalent characteristic values of the layers L1, L2, L3 and L4 are summarized in the following Table 3.

TABLE 3
Equivalent Characteristic Values

| | | Young's | Poisson's |
|---|---|---|---|
| | Stress (MPa) | modulus (GPa) | ratio |
| 1'st layer | 256 | 157 | 0.21 |
| 2'nd layer | 140 | 70 | 0.28 |
| 3'rd layer | −640 | 220 | 0.22 |
| 4'th layer | −100 | 100 | 0.25 |

By means of the aforementioned methods, the second interconnection layer E, which in reality is formed of the complicated layer structure comprising the first through fourth layers L1, L2, L3 and L4 as shown in FIG. 4, is mathematically transformed into the simplified layer structure having unit layers L1′, L2′, L3′, and L4′ as shown in FIG. 5. This mathematical transformation enables the wafer warpage to be reliably and accurately estimated using Stoney's formula, as described above.

In the same way that the equivalent characteristic values of the second interconnection layer E were used in the above example to convert the actual complicated layer structure into the mathematically equivalent unit film structure, all of the layers forming the semiconductor device can similarly be mathematically transformed into the equivalent structures of unit films to estimate wafer warpage from the mechanical characteristic values of the whole layer (step S4 in FIG. 3). The wafer warpage may then be estimated by means of a known and familiar simulation tool for evaluating conditions of wafer warpage from the mechanical characteristic values of unit film layers deposited on the substrate. For instance, as described above, the wafer warpage may be reliably estimated for a structure comprised of unit films by applying the converted equivalent characteristic values to Stoney's formula.

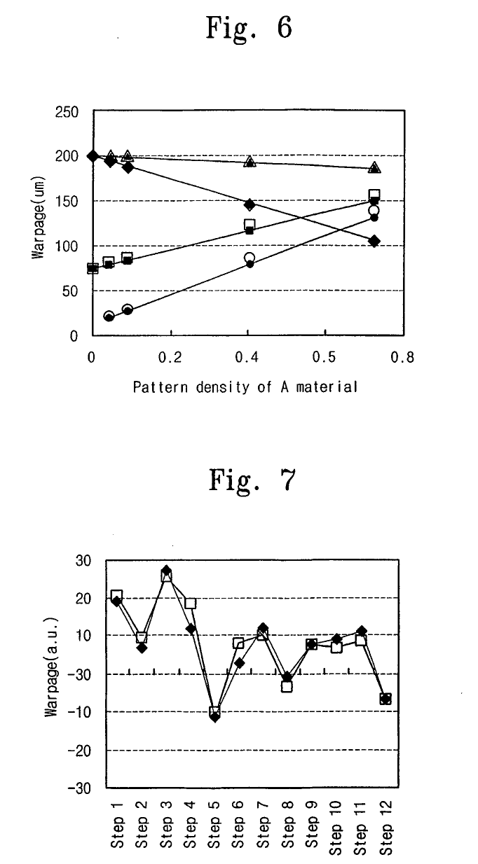

FIGS. 6 and 7 are graphs illustrating the results of carrying out a wafer warpage simulation according to an embodiment of the invention, comparing an estimated result for wafer warpage using the methods of the present invention with the actual result of warpage measured from a wafer where the fabrication process has been completed. FIG. 6 is a graph depicting warpage of a wafer having a simple pattern that is formed of two materials different in stress, in order to compare the results of warpage as estimated by the present invention with actual warpage measurement. FIG. 7 is a graph depicting the results of warpage as estimated by the present invention with actual warpage measurements compared at each of twelve semiconductor processing steps.

In FIG. 6, the solid dots represent actual results measured from the wafer, while the vacant dots represent estimation results of wafer warpage by the methods of this invention. The materials used were of two kinds, which may be referred to simply as A and B types. The four solid lines in FIG. 6 denote warpage features of wafers where the stress ratios of A:B are 1 Gigapascals (GPa):0 GPa, 0 GPa:1 GPa, 1GPa:1 GPa, and 0.5 GPa: 1 GPa, respectively.

From the graph of FIG. 6, it can be seen that the results of wafer warpage as actually measured from the actual wafer substantially agree with the wafer warpage values estimated by the embodiment of the invention within an error range of about 10% or less. Thus, the simulation method for wafer warpage according to the present invention enables substantially correct wafer warpage estimation within the error range of 10%.

In addition to the results comparing wafer warpage measurements according to pattern density on a wafer where the layers have been completely formed, as in FIG. 6, FIG. 7 shows that wafer warpage simulation by the methods of this invention is able to offer substantially correct results of warpage estimation even while conducting a series of sequential semiconductor processing steps. The graph of FIG. 7 comparatively shows actual wafer warpage results measured from a wafer according to processing steps and wafer warpage values as estimated by the methods of this invention at each of those processing steps. In FIG. 7, vacant dots represent the actually measured results of wafer warpage, while solid dots represent the estimated values of wafer warpage by the methods of this invention. From the graph of FIG. 7, it can be seen that the actually measured results almost completely agree with the estimated values. Thus, the present invention offers convenience in developing processing technology capable of estimating and correcting wafer warpage during a semiconductor fabrication process, as well as after completing the fabrication process. Furthermore, even after completing the fabrication process, it is possible to determine the thickness of a wafer before and after grinding the back side of the wafer, and, based on this information, to estimate wafer warpage before and after grinding the back side of the wafer.

According to the present invention, a semiconductor device constructed with a complicated structure using various materials, can be mathematically transformed into a mathematically equivalent stacked structure with pluralities of unit layers; then, utilizing values of mechanical characteristics which are obtained from the transformed layer structure, it is possible to reliably estimate wafer warpage for the device. As a result, it is possible to complete an operation of wafer warpage simulation that contains information about pattern density of the semiconductor device.

The present invention offers an advantage in developing processing technology capable of estimating wafer warpage during a semiconductor fabrication process, as well as after completing the fabrication process. Thus, it is possible to form films and patterns on a wafer in uniformity by means of processing techniques equipped with wafer warpage correction based on the methods of this invention.

According to the invention, it is possible to mathematically transform a complicated layer structure into the substantially equivalent form of a unit film structure, and to estimate wafer warpage by means of a simulation tool, thereby providing estimation results of warpage in either a chip-scaled version, where independent semiconductor chips are separated from the wafer, or in a wafer-scaled version as well.

While the present invention has been described in connection with the embodiments of the present invention illustrated in the accompanying drawings, it is not limited thereto. It will be apparent to those skilled in the art that various substitution, modifications and changes may be made thereto without departing from the scope and spirit of the invention.

What is claimed is:

1. A method of simulating wafer warpage, comprising the steps of:
dividing a semiconductor chip on a wafer into layers;
calculating the composition ratios of the materials forming each such layer;
determining equivalent characteristic values for each layer, based on mathematically transforming a layer into a substantially equivalent unit film structure, using the composition ratios and characteristic values of the materials forming the layer; and
estimating the wafer warpage from the equivalent characteristic values of the layers.

2. The method as set forth in claim 1, wherein the composition ratios of the materials of each layer are calculated from areal ratios designed in a layout.

3. The method as set forth in claim 1, wherein the step of dividing the layers comprises dividing vertically stacked layers by horizontal planes at the locations where materials discontinuously vary in composition.

4. The method as set forth in claim 3, wherein a thickness of a layer is measured as an interval between the horizontal planes at which the materials discontinuously vary in composition.

5. The method as set forth in claim 1, wherein the equivalent characteristic values are average values of characteristics based on the composition ratios of the materials forming the layer.

6. The method as set forth in claim 1, wherein the step of estimating the wafer warpage is carried out by regarding the wafer as a wafer including stacked layers composed of unit films having the equivalent characteristic values of the actual stacked layers.

7. The method as set forth in claim 1, wherein the step of estimating the wafer warpage is carried out before grinding the backside of the wafer.

8. The method as set forth in claim 7, wherein the composition ratios of the materials forming a layer are calculated from areal ratios designed in a layout of the semiconductor chip and scribing lines over the wafer.

9. The method as set forth in claim 1, wherein the step of estimating the wafer warpage is carried out after grinding the backside of the wafer.

10. The method as set forth in claim 9, wherein the composition ratios of the materials forming a layer are calculated from areal ratios designed in a layout of the semiconductor chip and scribing lines over the wafer.

11. The method as set forth in claim 1, wherein the step of estimating the wafer warpage is carried out after separating the semiconductor chip from the wafer.

12. The method as set forth in claim 11, wherein the composition ratios of the materials forming the layer are calculated from areal ratios designed in a layout of the semiconductor chip.
